(19) United States
(12) Patent Application Publication
(10) Pub. No.: US 2007/0026616 A1
(43) Pub. Date: Feb. 1, 2007

(54) Method for fabricating semiconductor device and semiconductor device fabricated using the same

(75) Inventor: Byung Soo Eun, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-Shi (KR)

(21) Appl. No.: 11/272,568

(22) Filed: Nov. 10, 2005

(30) Foreign Application Priority Data
Jul. 29, 2005 (KR) 2005-69740

(51) Int. Cl. H01L 21/336

(52) U.S. Cl. 438/299

(57) ABSTRACT

Provided are a method for fabricating a semiconductor device and a semiconductor device fabricated using the same. The method for fabricating a semiconductor device comprises forming gate stacks on a semiconductor substrate, forming gate spacers made of a dielectric material having a dielectric constant of 2 to 4, on the sides of the gate stacks, forming an interlayer dielectric film on the resulting structure and etching the interlayer dielectric film, thereby forming a landing plug contact hole, and filling the landing plug contact hole with a conductive material, thereby forming a landing plug contact. The semiconductor device fabricated according to the above-mentioned method comprises a semiconductor substrate, gate stacks formed on the predetermined regions of the semiconductor substrate, gate spacers formed on the sides of the gate stacks, an interlayer dielectric film formed on the gate stacks and semiconductor substrate, such that only the semiconductor substrate between gate stacks is exposed, and conductive landing plug contact filling the region from which the semiconductor substrate between the gate stacks is exposed.

### BACKGROUND OF THE INVENTION

1. Field of the Invention

The present invention relates to a method for fabricating a semiconductor device, and more particularly to a method for fabricating a semiconductor device involving forming a gate spacer utilizing silicon hydro-carbonate (SiHC) having a dielectric constant of about 2.

2. Description of the Related Art

Recently, in connection with the development of semiconductor devices, a process to increase the capacitance of a storage capacitor for storing electric charges discharged from a drain plays a very important role in early development stages of devices. Even though there are a variety of reasons to increase capacitance of the storage capacitor, the most important are as follows.

In volatile memories such as dynamic random access memories (DRAMs), continuous storage of data in memory cells requires periodic replenishment of electric charges, called a “refresh process”. Such a refresh process consumes a large quantity of electric power and therefore may serve as a major drawback particularly in mobile devices.

As such, there is a need to overcome such problems by increasing the refresh rate. As methods to increase the refresh rate, there may be mentioned a method of increasing capacitance (Cs) of the storage capacitor in the cell, or a method of decreasing parasitic capacitance (Cb) in the cell.

As methods to increase capacitance (Cs) of the storage capacitor, there may be exemplified a method entailing increasing a cell area or a method involving utilization of a material having a high dielectric constant as a material for the capacitor. However, the method of increasing a cell area has almost reached the limit of design rules, and application of novel materials having a high dielectric constant also involves a major investment and a great deal of research, thus resulting in difficulty to enter practical application.

Therefore, at present, the best way to increase capacitor capacitance is to reduce parasitic capacitance which is present in series with the storage capacitance inside the semiconductor device and decreases the overall capacitance of the cell.

Among various causes of parasitic capacitance, parasitic capacitance due to dielectric films present between gate lines and between bit lines exerts greatest influence on cell capacitance. In particular, as design rules have recently become stricter, pitches of the gate line and bit line become smaller and heights thereof become relatively high. As a result, an aspect ratio of the line is significantly increased, resulting in remarkable increase of parasitic capacitance.

As a solution to such problems mention may be made of a method wherein heights of gate line and bit line electrodes are decreased, i.e., a method wherein parasitic capacitance is decreased.

In general, after formation of the gate lines, a landing plug contact is formed between gate lines by forming a contact via use of a self-aligned contact (SAC) process wherein etching based on difference in an etching rate between the hardmask film of gate line, and between the nitride film and oxide film used as a gate spacer, is carried out, and then depositing polysilicon, as a material for forming a landing plug contact, via use of chemical vapor deposition (CVD).

Herein, a spacer nitride film used as a barrier of the SAC process exhibits a relatively low etching rate as compared to the oxide film and thus is suitable for use in the SAC process, but has a relatively high dielectric constant of about 8, which in turn leads to a high parasitic capacitance value, thereby lowering capacitance of the storage capacitor. That is, such parasitic capacitance is connected in series to storage capacitance and thus serves to lower the overall capacitance of the cell.

Accordingly, replacement of materials constituting the gate spacer with materials having a low dielectric constant decreases the parasitic capacitance value of the cell, leading to increased storage capacitance of the cell and thereby it is possible to reduce the refresh cycle, thus lowering power consumption of the semiconductor device and increasing operating speed of cells.

### SUMMARY OF THE INVENTION

Therefore, the present invention has been made in view of the above problems, and it is an object of the present invention to provide a method for fabricating a semiconductor device, capable of reducing parasitic capacitance thereof.

It is another object of the present invention to provide a semiconductor device fabricated using the above-mentioned method.

Technical problems to be solved by the present invention are not limited to above-mentioned problems, and any other technical problems, which were not mentioned above, would be obviously appreciated by those skilled in the art from the following description.

In accordance with an aspect of the present invention, the above and other objects can be accomplished by the provision of a method for fabricating a semiconductor device, comprising:

forming gate stacks on a semiconductor substrate;

forming gate spacers made of a dielectric material having a dielectric constant of 2 to 4, on the sides of the gate stacks;

forming an interlayer dielectric film on the resulting structure and etching the interlayer dielectric film, thereby forming a landing plug contact hole; and

filling the landing plug contact hole with a conductive material, thereby forming a landing plug contact.

In accordance with another aspect of the present invention, there is provided a semiconductor device, comprising:

a semiconductor substrate;

gate stacks formed on the predetermined regions of the semiconductor substrate;

gate spacers formed on the sides of the gate stacks;

an interlayer dielectric film formed on the gate stacks and semiconductor substrate, such that only the semiconductor substrate between the gate stacks is exposed; and

a conductive landing plug contact filling the region from which the semiconductor substrate between the gate stacks is exposed.

Specific details of other aspects and embodiments are encompassed in the detailed description and accompanying drawings.

These and other objects, advantages and features of the present invention and methods of achieving the same will become apparent from the detailed embodiments given below which are made in conjunction with the following drawings. This invention may, however, be embodied in different forms and should not be construed as being limited to the embodiments set forth herein. Rather, these embodiments are provided so that this disclosure will be thorough and complete, and will fully convey the scope of the invention to those skilled in the art. Therefore, the present invention should be defined by attached claims only. In the drawings, like numbers refer to like elements throughout the specification.

Further, in the drawings, the thicknesses and dimensions of layers and films or regions are exaggerated for clarity of the specification. It will also be understood that when a layer or film is referred to as being “on” another layer or film, it can be put directly on the other layer or film, or intervening layers or films may also be present.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a process flow chart illustrating a method for fabricating a semiconductor device in accordance with one embodiment of the present invention;

FIGS. 2a through 2i are process cross-sectional views in respective process steps of FIG. 1; and

FIG. 3 is a cross-sectional view showing a semiconductor device in accordance with one embodiment of the present invention.

### DESCRIPTION OF THE PREFERRED EMBODIMENTS

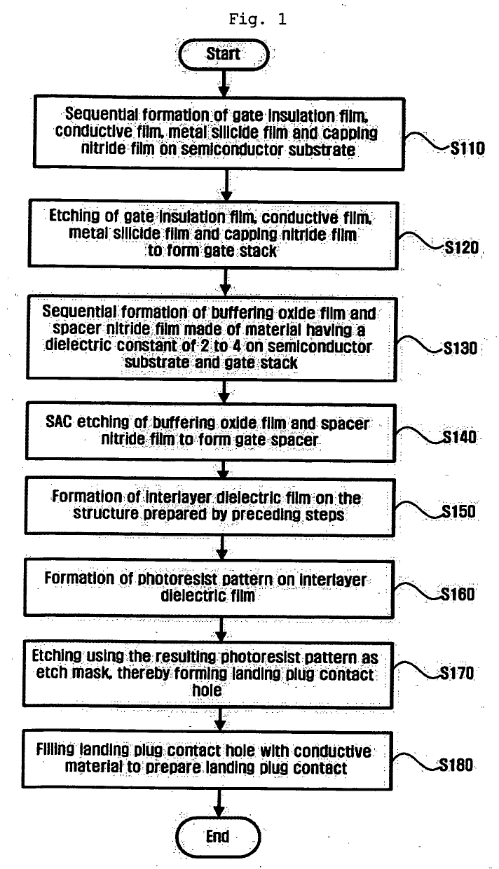

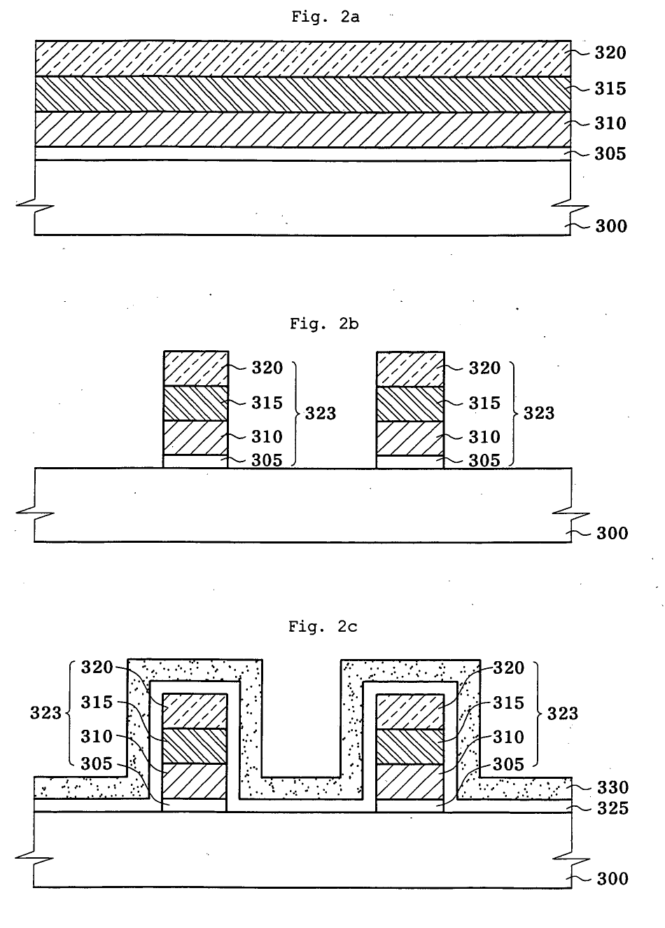

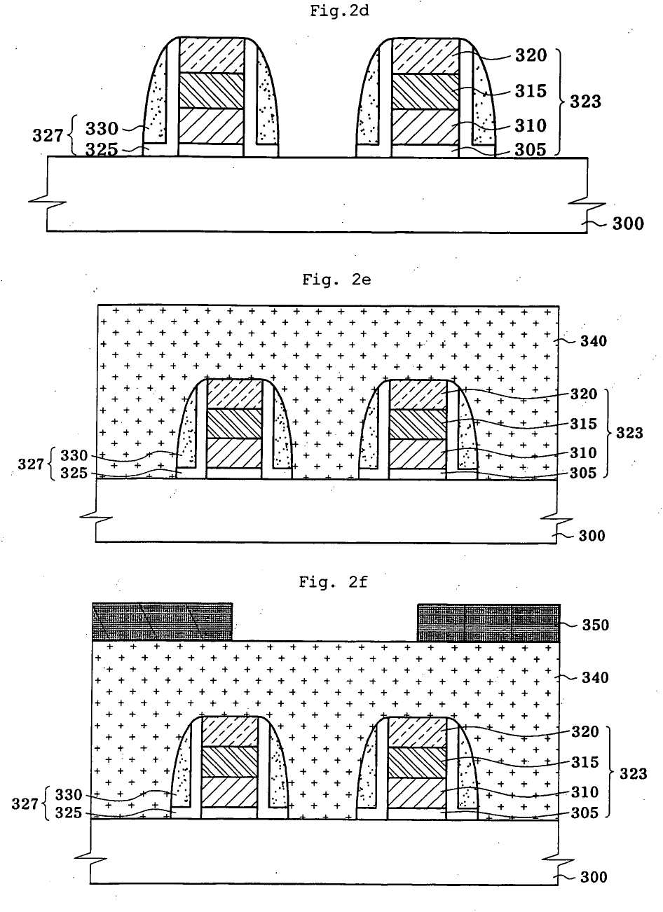

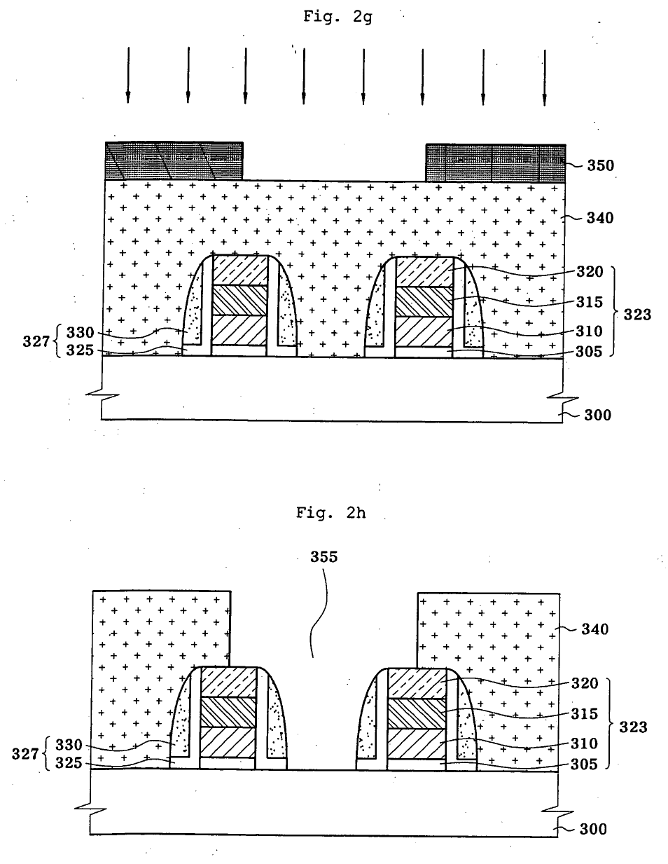

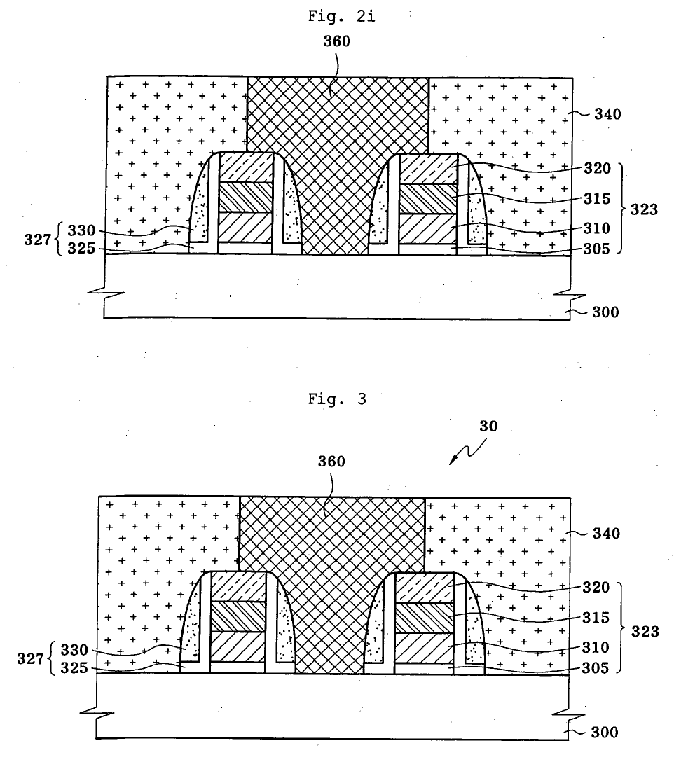

FIG. 1 is a process flow chart illustrating a method for fabricating a semiconductor device in accordance with one embodiment of the present invention, and FIGS. 2a through 2i show process cross-sectional views in respective process steps of FIG. 1.

In order to fabricate a semiconductor device in accordance with one embodiment of the present invention, as shown in FIG. 2a, a gate insulation film 305, a conductive film 310, a metal silicide film 315 and a hard mask film 320 are first sequentially formed on a semiconductor substrate 300 (S110)

The gate insulation film 305 is used as a dielectric of a gate electrode and is usually made of an oxide film of SiO₂. The gate insulation film 305 may be formed via use of thermal oxidation by oxygen diffusion or chemical vapor deposition (CVD) using an evaporator.

The conductive film 310 is formed on the gate insulation film 305, and polysilicon or a metal electrode may be employed as a material constituting the conductive film 310. The conductive film 310 serves as a gate electrode when the metal silicide film 315 is not formed later thereon. However, when the metal silicide film 315 is formed later on the conductive film 310, doped polysilicon is generally employed as the conductive film 310. In this connection, the conductive film 310 functions to improve adhesion to the metal silicide film 315 which will be formed later and to buffer stress.

The metal silicide film 315 is made of a metal, for example, a tungsten/silicon compound (WSiₓ), and is formed on the conductive film 310. Since the conductive film 310 made of doped polysilicon exhibits a relatively high electrical resistance, thus resulting in lowered operating speed of the gate electrode, the metal silicide film 315 is formed of tungsten silicide (WSiₓ) having lower electrical resistance and superior thermal properties as compared to polysilicon, in order to reduce gate resistance.

The hard mask film 320 is formed on the metal silicide film 315 and is made of primarily silicon nitride (SiNₓ). A nitride film such as silicon nitride (SiNₓ) film is generally employed as the hard mask film 320.

Next, as shown in FIG. 2b, the gate insulation film 305, conductive film 310, metal silicide film 315 and hard mask film 320 are etched to prepare gate stacks 323 (S120).

The gate stack 323 is also referred to as a gate electrode pattern, and may be composed of a gate insulation film 305/conductive film 310, or may be composed of the gate insulation film 305/conductive film 310/metal silicide film 315/hard mask film 320, as described hereinbefore.

More specifically describing formation of the gate stack 323, a photoresist pattern is first formed on the hard mask film 320 of FIG. 2a, and the hard mask film 320 is etched using the photoresist pattern as an etch mask, thereby forming a hard mask film pattern. Then, a metal silicide film 315, conductive film 310 and the gate insulation film 305 are sequentially etched using the resulting hard mask film pattern as an etch mask, thereby preparing gate stacks 323.

Herein, in order to prevent scattered reflection of light upon exposure, an anti-reflection layer may be further formed between the hard mask film 320 and photoresist pattern.

Next, as shown in FIG. 2c, a buffer film 325 and a gate spacer film 330 are sequentially formed on the semiconductor substrate 300 and gate stacks 323 (S130).

The buffer film 325 conforms to the semiconductor substrate 300 on which the gate stacks 323 were not formed and the gate stacks 323. The buffer film 325 functions to buffer stress occurring between the hard mask film 320 and spacer nitride film 330, and therefore formation thereof is optional.

The gate spacer film 330 is formed on the buffer film 325 and serves to prevent thermal diffusion due to a post thermal process.

As a material for the gate spacer film 330, silicon nitride (SiNₓ) has been conventionally employed. However, the silicon nitride film has a relatively high dielectric constant of about 8 and thus presents problems associated with increases in the overall parasitic capacitance of the cell. As such, the present invention employs a material having a dielectric constant of about 2 to 4, specifically silicon hydro-carbonate (SiHC), as a material for the spacer film 330.

Upon use of SiHC as the spacer film 330, the spacer film 330 advantageously has a low dielectric constant, and can be employed as an excellent H₂ barrier due to a lower diffusion rate against H₂ as compared to conventional nitride films, thus being capable of improving properties such as short channel effects caused by H₂ ions.

A variety of methods can be employed to deposit SiHC, but chemical vapor deposition (CVD) is most preferred.

Next, as shown in FIG. 2d, the gate spacer film 330 and buffer film 325 are etched by a self-aligned contact (SAC) etching, thereby forming gate spacers 327 (S140).

The gate spacer 327 serves as a mask in a subsequent lightly doped drain (LDD) process or upon SAC etching associated with formation of a landing plug contact hole.

Next, as shown in FIG. 2e, an interlayer dielectric film 340 is formed over the entire surface of the structure which was formed in the preceding steps (S150).

The interlayer dielectric film 340 provides electrical insulation between gate lines, and is usually formed of materials such as Phosphosilicate Glass (PSG), Boron Phosphosilicate Glass (BPSG) and SiOₓ.

Next, as shown in FIG. 2f, photoresist patterns 350 are formed on the interlayer dielectric film 340 (S160).

The photoresist patterns 350 are formed by application to the interlayer dielectric film 340 via spin coating, followed by exposure and development, and is used later as an etch mask in formation of a landing plug contact hole by etching the interlayer dielectric film 340.

Next, as shown in FIG. 2g, etching is carried out using the photoresist patterns 350 as an etch mask, thereby forming a landing plug contact hole 355 which allows the semiconductor substrate 300 between the gate stacks 323 to be exposed, as shown in FIG. 2h (S170).

The landing plug contact hole 355 is formed by SAC etching, i.e., taking advantage of the difference in etching rates between the nitride film and oxide film.

More specifically describing formation of the landing plug contact hole 355, since the oxide film such as an interlayer dielectric film 340 generally exhibits a higher etching rate than the nitride film constituting the gate spacers 327 and hard mask films 320, most of the oxide film is etched, but the nitride film is slowly etched, upon practically performing an etching process. As a result, the oxide film, among regions in which the photoresist patterns were not formed, is intensively etched, thereby forming the landing plug contact hole 355, as shown in FIG. 2h.

Finally, as shown in FIG. 2i, the landing plug contact hole 355 is filled with a conductive material, thereby completing formation of a landing plug contact 360 (S180).

The landing plug contact 360 provides electrical connection between bit lines which will be formed later and the active region of the semiconductor substrate 300, and is formed of mainly polysilicon.

FIG. 3 is a cross-sectional view showing a semiconductor device in accordance with one embodiment of the present invention.

Herein, among reference numerals used in FIG. 3, the same reference numerals as in the description of FIG. 2a through FIG. 2i refer to like elements.

As such, specific nature of the respective elements refers to the details discussed hereinbefore, and thus the structure of the semiconductor device in accordance with the embodiment of the present invention will now be described.

As shown in FIG. 3, a semiconductor device in accordance with the present invention includes a semiconductor substrate 300, gate stacks 323, gate spacers 327, interlayer dielectric films 340 and a landing plug contact 360.

The respective gate stacks 323 may be composed of a gate insulation film 305/conductive film 310 or may be composed of the gate insulation film 305/conductive film 310/metal nitride film 315/hard mask film 320, and are formed on the predetermined positions of the semiconductor substrate 300.

The gate spacers 327 are formed on side walls of the gate stacks 323, and are composed of buffer films 325 adjoining the gate stacks 323 and gate spacer films 330 formed on the buffer films 325. Herein, the present invention employs a low-dielectric material having a dielectric constant of about 2 to 4, specifically silicon hydro-carbonate (SiHC), instead of a conventional nitride film, as a material for formation of the gate spacer films 330.

The landing plug contact 360 is formed on the semiconductor substrate 300 exposed between gate stacks 323, and provides electrical connection between bit lines which will be formed later on interlayer dielectric films 340 and the active region of the semiconductor substrate 300.

As apparent from the above description, in accordance with a method for fabricating a semiconductor device of the present invention and a semiconductor device fabricated using the same, it is possible to implement a semiconductor device capable of improving properties such as short channel effects by preventing formation of parasitic capacitance exhibited when a conventional nitride film is used as a spacer, thereby increasing cell capacitance and having an effective barrier against H₂ ions.

Although the preferred embodiments of the present invention have been disclosed with reference to the accompanying drawings, the present invention may be embodied in different forms and should not be misconstrued as being limited to the embodiments set forth herein, and those skilled in the art will appreciate that various modifications, additions and substitutions are possible without departing from the scope and spirit of the invention as disclosed in the accompanying claims. Therefore, it should be understood that the embodiments disclosed herein are provided only for illustrating the present invention and should not be construed as limiting the scope and spirit of the present invention.

What is claimed is:

1. A method for fabricating a semiconductor device, comprising:
forming gate stacks on a semiconductor substrate;
forming gate spacers made of a dielectric material having a dielectric constant of 2 to 4, on the sides of the gate stacks;
forming an interlayer dielectric film on the resulting structure and etching the interlayer dielectric film, thereby forming a landing plug contact hole; and
filling the landing plug contact hole with a conductive material, thereby forming a landing plug contact.

2. The method according to claim 1, wherein the dielectric material is silicon hydro-carbonate (SiHC).

3. The method according to claim 1, wherein the gate stack is composed of a gate insulation film formed on the semiconductor substrate and a conductive film formed on the gate insulation film.

4. The method according to claim 1, wherein the gate stack is composed of a gate insulation film formed on the semiconductor substrate, a conductive film formed on the gate insulation film, a metal silicide film formed on the conductive film and a hard mask film formed on the metal silicide film.

5. A semiconductor device, comprising:
a semiconductor substrate;
gate stacks formed on the predetermined regions of the semiconductor substrate;
gate spacers formed on the sides of the gate stacks and made of a dielectric material having a dielectric constant of 2 to 4;
an interlayer dielectric film formed on the gate stacks and semiconductor substrate, such that only the semiconductor substrate between gate stacks is exposed; and
a conductive landing plug contact filling the region from which the semiconductor substrate between the gate stacks is exposed.

6. The semiconductor device according to claim 5, wherein the dielectric material is silicon hydro-carbonate (SiHC).

7. The semiconductor device according to claim 5, wherein the gate stack is composed of a gate insulation film formed on the semiconductor substrate and a conductive film formed on the gate insulation film.

8. The semiconductor device according to claim 5, wherein the gate stack is composed of a gate insulation film formed on the semiconductor substrate, a conductive film formed on the gate insulation film, a metal silicide film formed on the conductive film and a hard mask film formed on the metal silicide film.

9. The semiconductor device according to claim 5, further comprising:
a buffer film for improving interface properties of the gate spacer and gate stack, between the gate spacer and gate stack.
